(19) United States
(12) Patent Application Publication
(10) Pub. No.: US 2014/0145310 A1
(43) Pub. Date: May 29, 2014

(54) THIN FILM DEVICE, METHOD OF MANUFACTURING THE SAME, AND METHOD OF MANUFACTURING DISPLAY

(71) Applicant: Sony Corporation, Tokyo (JP)

(72) Inventor: Ryuto Akiyama, Kanagawa (JP)

(73) Assignee: Sony Corporation, Tokyo (JP)

(21) Appl. No.: 14/086,241

(22) Filed: Nov. 21, 2013

(30) Foreign Application Priority Data
Nov. 29, 2012 (JP) 2012-261431

(51) Int. Cl. H01L 29/786; H01L 21/288; H01L 21/28; H01L 21/02

(52) U.S. Cl. CPC H01L 29/786; H01L 21/02227; H01L 21/288; H01L 21/28008; H01L 21/02518
USPC 257/618; 438/759; 438/674; 438/585; 438/479

(57) ABSTRACT

A method of manufacturing a thin film device, the method includes: forming a functional film having a predetermined pattern on a surface of a first substrate; covering the surface of the first substrate and the functional film with an insulating film; and transferring the insulating film and the functional film from the first substrate to a second substrate.

### CROSS REFERENCE TO RELATED APPLICATIONS

This application claims the benefit of Japanese Priority Patent Application JP 2012-261431 filed Nov. 29, 2012, the entire contents of which are incorporated herein by reference.

### BACKGROUND

The present technology relates to a thin film device including a functional film such as an electrically-conductive film and a semiconductor film, to a method of manufacturing the thin film device, and to a method of manufacturing a display.

A thin film transistor (TFT) includes a gate electrode (a gate line), a semiconductor film, and source-drain electrodes (source lines), and is used in wide-range fields, for example, a field of high-resolution displays etc. Such a TFT is applied, as a switching device, to a display of an active matrix type, and achieves increase in size of the display. However, on the other hand, the above-described lines in the TFT become longer in accordance with the increase in size. Therefore, resistance of lines becomes higher disadvantageously.

Moreover, in recent years, in order to achieve a display having high density (high definition) and high aperture ratio, it has been desirable to form thinner lines, which also cause increase in resistance of the lines. Such increase in resistance of the lines causes delay in transmitting signals. Accordingly, display quality may be degraded. Against this, it may be considered to increase a thickness of the lines, and thereby to suppress the increase in resistance of the lines. However, in this method, a level difference becomes larger as the thickness of the lines is increased. Therefore, disconnection defect may be easily caused in lines in upper layers.

Therefore, in order to eliminate such a level difference formed by the functional films such as lines, there is proposed a method to provide a trench on a surface of an insulating substrate, and to fill the trench with the functional film (for example, see Japanese Unexamined Patent Application Publication Nos. H6-163586, H4-324938, H7-333648, 2003-78171, and 2008-251814 (hereinafter referred to as JP H6-163586A, JP H4-324938A, JP H7-333648A, JP 2003-78171A, and JP 2008-251814A, respectively)).

### SUMMARY

In such an embedded-type functional film, a burr etc. may be caused on the functional film during a formation process thereof, and flatness of a surface may be degraded.

It is desirable to provide a thin film device having high flatness, a method of manufacturing such a thin film device, and a method of manufacturing a display.

According to an embodiment of the present technology, there is provided a method of manufacturing a thin film device, the method including: forming a functional film having a predetermined pattern on a surface of a first substrate; covering the surface of the first substrate and the functional film with an insulating film; and transferring the insulating film and the functional film from the first substrate to a second substrate.

According to an embodiment of the present technology, there is provided a method of manufacturing a display, the method including forming a thin film device. The forming includes: forming a functional film having a predetermined pattern on a surface of a first substrate; covering the surface of the first substrate and the functional film with an insulating film; and transferring the insulating film and the functional film from the first substrate to a second substrate.

In the method of manufacturing the thin film device and the method of manufacturing the display according to the above-described embodiments of the present technology, the functional film and the insulating film are formed in accordance with the surface of the first substrate so that a surface of the functional film and a surface of the insulating film configure the same plane after the transferring.

According to an embodiment of the present technology, there is provided a thin film device including: an insulating film; and a functional film embedded in the insulating film and having a surface that configures a same plane configured of a surface of the insulating film, the functional film including a protrusion portion protruding toward a back surface of the insulating film.

In the thin film device according to the above-described embodiment of the present technology, the surface on one side of the functional film and the surface of the insulating film configure the same plane. Therefore, occurrence of disconnection etc. caused by the level difference due to the functional film is suppressed. The functional film is formed by being formed on a substrate (first substrate) and then being transferred to another substrate (second substrate). The functional film has a protrusion portion protruding toward a back surface of the insulating film.

According to the thin film device, the method of manufacturing the thin film device, and the method of manufacturing the display of the above-described embodiments of the present technology, a transfer process is used. Therefore, an embedded-type functional film in accordance with the surface of the first substrate is formed. Therefore, occurrence of a burr etc. on the surface of the functional film is prevented, and high flatness is maintained.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1A is a plan view illustrating a configuration of a TFT according to an embodiment of the present technology.

FIG. 1B is a cross-sectional view taken along a line B-B of the TFT shown in FIG. 1A.

FIG. 2A is a detailed cross-sectional view of a gate electrode shown in FIG. 1B.

FIG. 2B is a plan view of a gate electrode shown in FIG. 2A.

FIG. 3 is a cross-sectional view illustrating another example of the gate electrode shown in FIG. 2A.

FIG. 4 is a cross-sectional view illustrating still another example of the gate electrode shown in FIG. 2A.

FIG. 5A is a cross-sectional view illustrating a process of manufacturing the TFT shown in FIG. 1B.

FIG. 5B is a cross-sectional view illustrating a process following the process shown in FIG. 5A.

FIG. 5C is a cross-sectional view illustrating a process following the process shown in FIG. 5B.

FIG. 5D is a cross-sectional view illustrating a process following the process shown in FIG. 5C.

FIG. 6 is a cross-sectional view illustrating a configuration in a case where a gate electrode pattern shown in FIG. 5A is formed by a printing method.

FIG. 7A is a cross-sectional view illustrating a process of manufacturing a TFT according to a comparative example.

FIG. 7B is a cross-sectional view illustrating a process following the process shown in FIG. 7A.

FIG. 7C is a cross-sectional view illustrating a process following the process shown in FIG. 7B.

FIG. 7D is a cross-sectional view illustrating a process following the process shown in FIG. 7C.

FIG. 7E is a cross-sectional view illustrating a process following the process shown in FIG. 7D.

FIG. 8 is a cross-sectional view illustrating a configuration of a TFT according to a modification.

FIG. 9 is a diagram illustrating a general configuration of a display including one of the TFTs shown in FIGS. 1A and 8.

FIG. 10A is an equivalent circuit diagram illustrating an example of a pixel drive circuit shown in FIG. 9.

FIG. 10B is a diagram illustrating another example of the pixel drive circuit shown in FIG. 10A.

FIG. 11A is a perspective view illustrating an appearance of Application Example 1.

FIG. 11B is a perspective view illustrating another example of an electronic book shown in FIG. 11A.

FIG. 12 is a perspective view illustrating an appearance of Application Example 2.

FIG. 13 is a perspective view illustrating an appearance of Application Example 3.

FIG. 14A is a perspective view illustrating an appearance of Application Example 4 viewed from a front side thereof.

FIG. 14B is a perspective view illustrating an appearance of Application Example 4 viewed from a back side thereof.

FIG. 15 is a perspective view illustrating an appearance of Application Example 5.

FIG. 16 is a perspective view illustrating an appearance of Application Example 6.

FIG. 17A includes a front view, a left-side view, a right-side view, and a top view of Application Example 7 in a closed state.

FIG. 17B is a front view and a side view of Application Example 7 in an open state.

### DETAILED DESCRIPTION

An embodiment of the present technology will be described below in detail with reference to the drawings. The description will be given in the following order.

### 1. Embodiment

TFT: an example in which an embedded-type gate electrode is formed

### 2. Modification

an example in which an embedded-type semiconductor film is formed

### 3. Application Example

Display

### EMBODIMENT

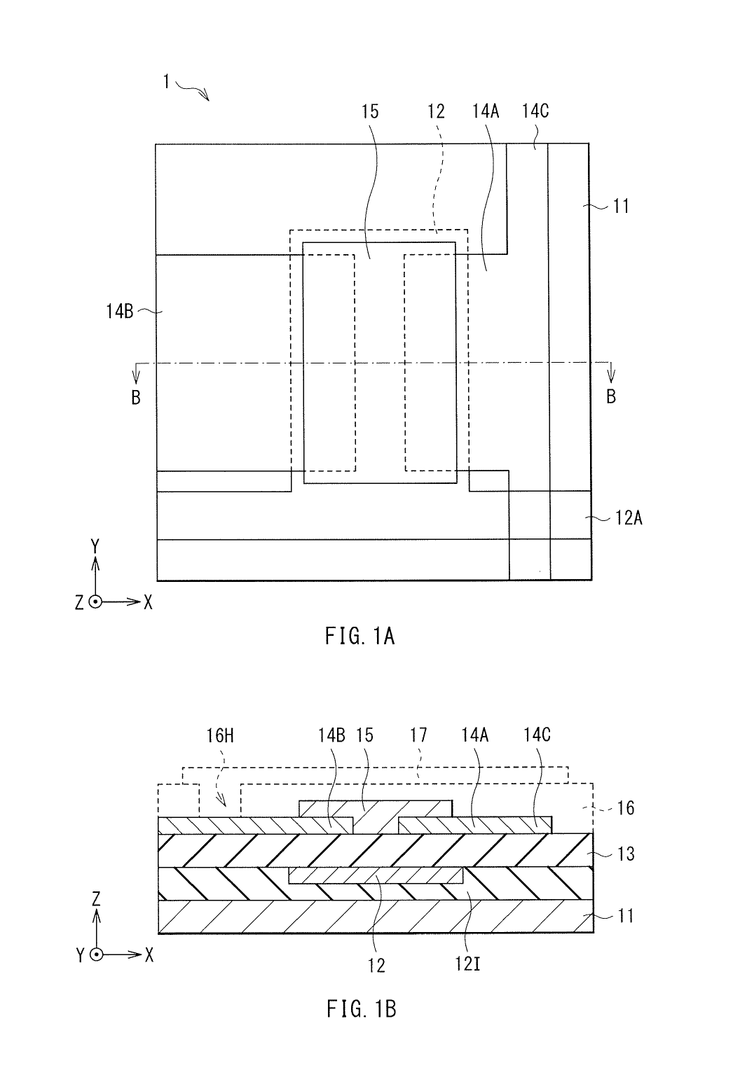

FIG. 1A illustrates a cross-sectional configuration of a TFT 1 (thin film device) according to an embodiment of the present technology. FIG. 1B illustrates a cross-sectional configuration taken along a line B-B in FIG. 1A. The TFT 1 is a field-effect transistor, and may be used as a driving device in a display using, for example, liquid crystal, organic EL, an electrophoretic display material, or the like. The TFT 1 has a so-called bottom-contact bottom-gate (inverted staggered) structure, and includes a gate electrode 12, a gate insulating film 13, a source electrode 14A, a drain electrode 14B, and a semiconductor film 15 in order on a substrate 11 (second substrate). In an upper layer of the semiconductor film 15, for example, a pixel electrode 17 may be formed with a passivation film 16 in between. The TFT 1 serves as the driving device of a display as described above.

The substrate 11 may be configured, for example, of a glass substrate, a quartz substrate, a plastic film, or the like having a thickness from about 20 nm to about 1 mm both inclusive. Examples of a material used for the plastic film may include polyethylene terephthalate, polyethylene naphthalate, polyether sulfone, polyether imide, polyether ether ketone, polyether ketone, polyphenylene sulfide, polyarylate, polyimide, polycarbonate, cellulose triacetate, cycloolefin polymer, polyolefin, polyvinyl chloride, liquid crystal polymer, epoxy resin, phenol resin, urea resin, melamine resin, and silicon resin. The foregoing resins may be used in mixture. When the substrate 11 is configured of the plastic film, flexibility of the TFT 1 is improved.

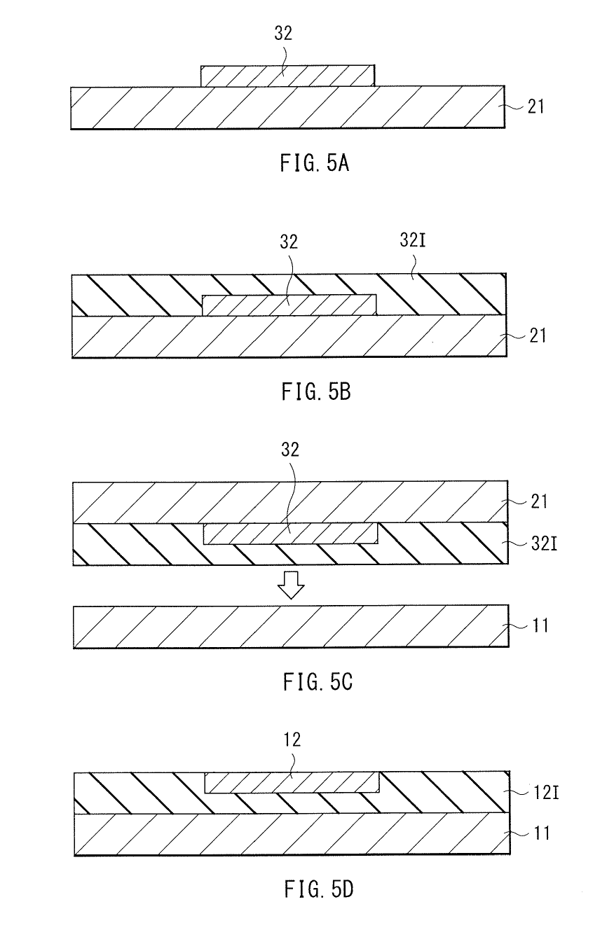

The gate electrode 12 has a role to apply a gate voltage to the TFT 1, and to control carrier density in the semiconductor film 15 by the gate voltage. The gate electrode 12 is electrically connected to a gate line 12A that extends in a predetermined direction (an X direction in FIG. 1A) and is provided so as to expand toward a direction (for example, a Y direction orthogonal to the X direction) that intersects with the extending direction of the gate line 12A. For example, the gate electrode 12 may be integrated with the gate line 12A. In the present embodiment, the gate electrode 12 and the gate line 12A are embedded in an insulating embedding film 12I (insulating film), and surfaces of the gate electrode 12 and the gate line 12A and a front surface (a surface in contact with the gate insulating film 13) of the embedding film 12I configure the same plane. In other words, the gate electrode 12 and the gate line 12A in the TFT 1 have an embedded structure. In such a way, a level difference caused by the thickness of the gate electrode 12 and the gate line 12A is eliminated, and disconnection in lines in upper layers (such as the source electrode 14A, the drain electrode 14B, and a source line 14C which will be described later) is prevented. As will be described later in detail, in this example, the embedded structure is formed by a transfer process. Therefore, high flatness is achieved utilizing a surface of a substrate for transfer (a transfer substrate 21 in FIG. 5A which will be described later). It is to be noted that, the phrase “the surfaces of the gate electrode 12 and the gate line 12A and the front surface of the embedding film 12I configure the same plane” encompasses a case in which the surfaces of the gate electrode 12 and the gate line 12A and the front surface of the embedding film 12I are on substantially the same plane in a degree which does not degrade the effect of the embodiment of the present technology, in addition to the case in which the surfaces of the gate electrode 12 and the gate line 12A and the front surface of the embedding film 12I are on completely the same plane. For example, the foregoing phrase encompasses a case in which fine asperities exist at a degree which does not influence the lines in upper layers due to errors caused by various factors such as manufacturing errors and variations.

The gate electrode 12 and the gate line 12A are provided in a selective region on the substrate 11. The gate electrode 12 and the gate line 12A each may be configured, for example, of a simple substance of chromium (Cr), iron (Fe), nickel (Ni), copper (Cu), zinc (Zn), germanium (Ge), palladium (Pd), platinum (Pt), silver (Ag), indium (In), tin (Sn), tellurium (Te), gold (Au), boron (B), manganese (Mn), aluminum (Al), silicon (Si), cobalt (Co), rhodium (Rh), or the like, or alloy thereof. As the alloy, for example, Cr—Ni, Fe—Si, Fe—Ni, Co—Ni, Fe—Co, Cu—Si, Cu—Sn, Pd—Pt, Ag—Pd, Ag—In, Ag—Au, Ag—Cu, Au—Ge, Au—Sn, Au—Pd, Fe—Pd, Co—Pd, Ni—Pd, or the like may be preferably used. The gate electrode 12 and the gate line 12A configured of such a material may be configured, for example, of a material obtained by firing metal nanoparticles having average particle diameter from 1 nm to 100 nm both inclusive. In this example, “particle diameter” refers to a geometrical particle diameter of each metal nanoparticle, and “average particle diameter” refers to typical particle diameter in the metal nanoparticle group. Metal nanoparticles have low melting point and exhibit low resistance after being fired. Therefore, the metal nanoparticles are suitable for the gate electrode 12 and the gate line 12A. The gate electrode 12 and the gate line 12A may be configured of a lamination of a plurality of simple substances of metal and/or alloys. Other than the above-described materials, inorganic electrically-conductive material, organic electrically-conductive material such as polyaniline, and/or carbon materials may be used for the gate electrode 12 and the gate line 12A. The gate electrode 12 and the gate line 12A may have, for example, a thickness from 50 nm to 200 nm both inclusive.

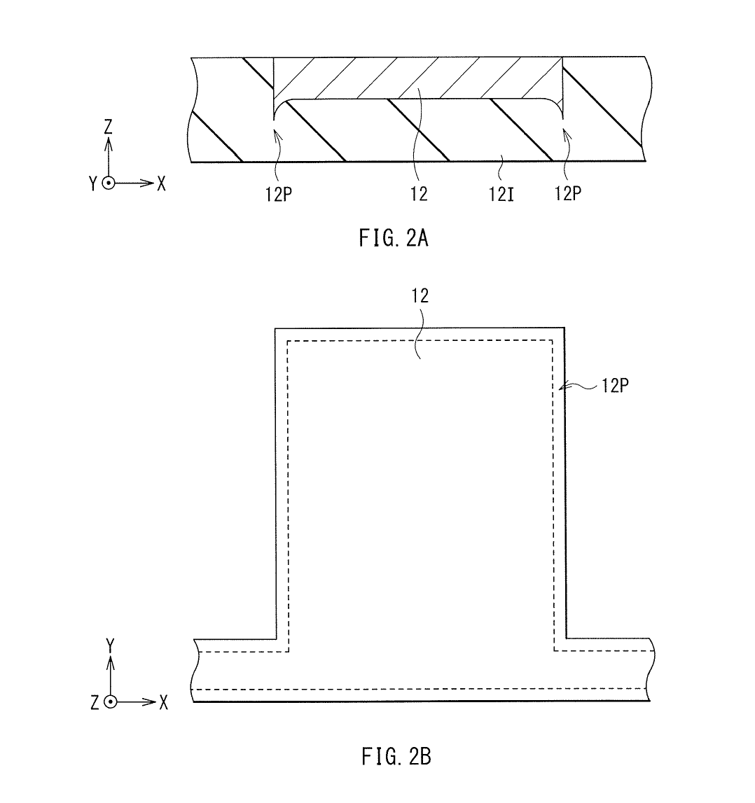

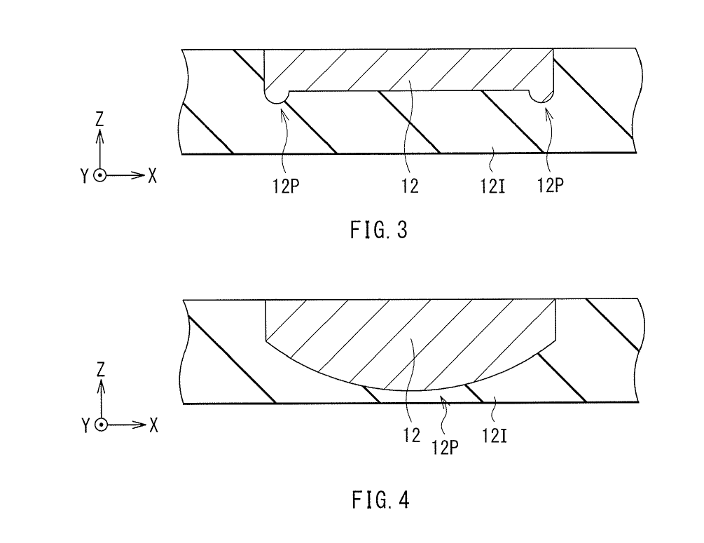

The gate electrode 12 and the gate line 12A may be formed, for example, by a printing method with the use of ink including metal nanoparticles such as those described above. As shown in FIGS. 2A and 2B, a protrusion portion 12P that protrudes toward the back surface (a surface on the substrate 11 side) of the embedding film 12I is provided in part or all of circumferential edges of the gate electrode 12 and the gate line 12A formed by such a printing method. The protrusion portion 12P may be provided, for example, in the entire circumferential edges of the gate electrode 12 and the gate line 12A. For example, when the ink is dried on the transfer substrate (the transfer substrate 21 in FIG. 5A which will be described later), solute becomes non-uniform, and thereby, the protrusion portion 12P is formed. Specifically, the coffee stain phenomenon during inkjet printing may be mentioned. The protrusion portion 12P may be configured of a so-called burr, which may be formed when reverse printing is performed and the ink is sheared on the transfer substrate, for example. A tip of the protrusion portion 12P may be pointed, or may be curved as shown in FIG. 3. As shown in FIG. 4, the protrusion portion 12P may be provided in central portions of the gate electrode 12 and the gate line 12A. Such a protrusion portion 12P may be formed, for example, by flowing ink on the transfer substrate when a method such as screen printing and gravure printing is used. The protrusion portion 12P may protrude having a height that is less than the thickness of the gate electrode 12 and the gate line 12A, for example.

The embedding film 12I is provided on an entire surface of the substrate 11. The front surface of the embedding film 12I has high flatness. The gate electrode 12 and the gate line 12A are exposed in part of the front surface of the embedding film 12I. The embedding film 12I may be made, for example, of an insulating resin material. Specific examples of such an insulating resin material may include styrene-based resins, epoxy-based resins, phenol-based resins, acryl-based resins, saturated-polyester-based resins, unsaturated-polyester-based resins, silicone-based resins, and fluorine-based resins. Such resins may be thermoset resins, thermoplastic resins, or photocurable resins which are curable by ultraviolet rays etc. The embedding film 12I may be configured of one resin material, or may be configured of a plurality of resin materials.

The gate insulating film 13 is provided for insulating the gate electrode 12 from the source electrode 14A, the drain electrode 14B, and the semiconductor film 15. The gate insulating film 13 is provided between the embedding film 12I in which the gate electrode 12 is embedded and the source electrode 14A, the drain electrode 14B, and the semiconductor film 15. The gate insulating film 13 may be made, for example, of an organic material such as polyvinyl phenol, polymethyl methacrylate, polyvinyl alcohol, polyimide, polyamide, polyester, polyvinyl acetate, polyurethane, polysulfone, polyvinylidene fluoride, cyanoethyl pullulan, epoxy resin, phenol resin, benzocyclobutene resin, and acryl resin. The gate insulating film 13 may be made, for example, of an inorganic material such as silicon oxide (SiO₂), aluminum oxide (Al₂O₃), and tantalum oxide (Ta₂O₅). The gate insulating film 13 may have a thickness, for example, of 50 nm to 1000 nm both inclusive.

A pair of the source electrode 14A and the drain electrode 14B is provided on the gate insulating film 13. The source electrode 14A and the drain electrode 14B are so arranged that a gap between the source electrode 14A and the drain electrode 14B faces the gate electrode 12. Top surfaces of such source electrode 14A and drain electrode 14B are in contact with the semiconductor film 15, and thereby, the source electrode 14A and the drain electrode 14B are electrically connected to the semiconductor film 15. The source electrode 14A is electrically connected to the source line 14C, and the source line 14C extends in a direction (Y direction) orthogonal to the gate line 12A. The source electrode 14A may be integrated, for example, with the source line 14C, and may expand in a direction (for example, the X direction orthogonal to the Y direction) intersecting with the extending direction of the source line 14C. The drain electrode 14B is so arranged as to face the source electrode 14A in the direction in which the source electrode 14A expands. The source electrode 14A, the drain electrode 14B, and the source line 14C are made of materials similar to that of the above-described gate electrode 12, and each may have a thickness, for example, from 50 nm to 200 nm both inclusive.

The semiconductor film 15 is provided on the top surfaces of the source electrode 14A and the drain electrode 14B and in the gap between the source electrode 14A and the drain electrode 14B, and faces the gate electrode 12. The semiconductor film 15 may be made, for example, of an organic semiconductor material. Specific examples thereof may include, polythiophene, poly-3-hexylthiophene [P3HT] obtained by introducing a hexyl group in polythiophene, pentacene[2,3,6,7-dibenzoanthracene], polyanthracene, naphthacene, hexacene, heptacene, dibenzopentacene, tetrabenzopentacene, chrysene, perylene, coronene, terylene, ovalene, quaterrylene, circumanthracene, benzopyrene, dibenzopyrene, triphenylene, polypyrrole, polyaniline, polyacetylene, polydiacetylene, polyphenylene, polyfuran, polyindole, polyvinyl carbazole, polyselenophene, polytellurophene, polyisothianaphthene, polycarbazole, polyphenylene sulfide, polyphenylene vinylene, polyvinylene sulfide, polythienylene vinylene, polynaphthalene, polypyrene, polyazulene, phthalocyanine such as copper phthalocyanine, merocyanine, hemicyanine, polyethylene dioxythiophene, pyridazine, naphthalene tetracarboxylic diimide, poly(3,4-ethylene dioxythiophene)/polystyrene sulfonate [PEDOT/PSS], 4,4′-biphenyl dithiol (BPDT), 4,4′-diisocyanobiphenyl, 4,4′-diisocyano-p-terphenyl, 2,5-bis(5′-thioacetyl-2′-thiophenyl)thiophene, 2,5-bis(5′-thioacetoxyl-2′-thiophenyl)thiophene, 4,4′-diisocyanophenyl, benzidine(biphenyl-4,4′-diamine), TCNQ (tetracyanoquinodimethane), electric charge transfer complex such as tetrathiafulvalene (TTF)-TCNQ complex, bis ethylene ditetrathiafulvalene (BEDTTTF)-perchlorate complex, BEDTTTF-iodine complex, and TCNQ-iodine complex, biphenyl-4,4′-dicarboxylic acid, 1,4-di(4-thiophenylacetylenyl)-2-ethylbenzene, 1,4-di(4-isocyanophenylacetylenyl)-2-ethylbenzene, dendrimer, fullerene such as C60, C70, C76, C78, and C84, 1,4-di(4-thiophenylethynyl)-2-ethylbenzene, 2,2″-dihydroxy-1,1′: 4′,1″-terphenyl, 4,4′-biphenyl diethanal, 4,4′-biphenyldiol, 4,4′-biphenyldiisocyanate, 1,4-diacetynylbenzene, diethylbiphenyl-4,4′-dicarboxylate, benzo[1,2-c; 3,4-c′; 5,6-c′]tris[1,2]dithiol-1,4,7-trithione, alpha-sexithiophene, tetrathiotetracene, tetraselenotetracene, tetratellurutetracene, poly(3-alkylthiophene), poly(3-thiophene-β-ethane-sulfonate), poly(N-alkylpyrrol)poly(3-alkylpyrrol), poly(3,4-dialkylpyrrol), poly(2,2′-thienylpyrrol), poly(dibenzothiophene sulfide), and quinacridone. Other than the foregoing materials, condensed polycyclic aromatic group compounds, porphyrin-based delivertives, phenyl-vinylidene-based conjugated oligomers, thiophene-based conjugated oligomers, etc. may be used. The semiconductor film 15 may be made of an inorganic material including oxide semiconductor material, silicon material, or the like. The semiconductor film 15 may have a thickness, for example, from 10 nm to 100 nm both inclusive.

Such a TFT 1 is covered with the passivation film 16, and the pixel electrode 17 on the passivation film 16 is electrically connected to the drain electrode 14B. In such a way, the TFT 1 is allowed to serve as the driving device of a display. The passivation film 16 is for protecting the semiconductor film 15, and is for planarizing the surface of the substrate 11 on which the TFT 1 is provided. The passivation film 16 includes a connection hole 16H. The pixel electrode 17 is electrically connected to the drain electrode 14B via the connection hole 16H. Examples of a material used to make the passivation film 16 may include silicon oxide, silicon nitride, aluminum oxide, aluminum nitride (AlN), tantalum oxide, and aluminum oxynitride (AlOₓN₁₋ₓ where X is from 0.01 to 0.2 both inclusive). Further, organic material such as polyvinyl alcohol, polyvinyl phenol, novolac resin, acrylic resin, and fluorine-based resin may be used. The pixel electrode 17 is provided on the passivation film 16 for each pixel, and may apply a voltage to a display layer (not illustrated) between the pixel electrode 17 and the common electrode (not illustrated), for example. The pixel electrode 17 may be configured, for example, of a metal film made of gold, silver, copper, aluminum, etc., an oxide film made of ITO etc., an organic electrically-conductive film made of PEDOT/PSS etc., or an electrically-conductive carbide-based material film made of carbon nanotube, graphene, etc.

Such a TFT 1 may be manufactured, for example, as follows.

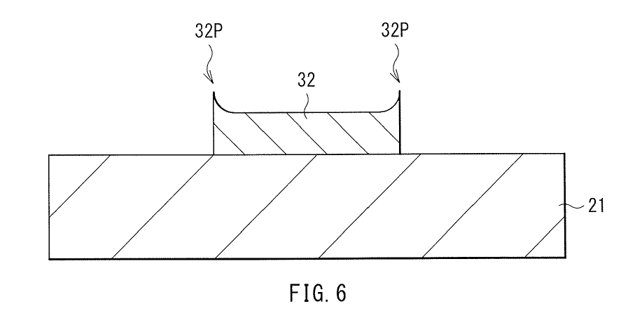

First, the gate electrode 12 and the gate line 12A that have the embedded structure (FIGS. 1A and 1B) are formed on the substrate 11 (FIGS. 5A to 5D). Specifically, first, the transfer substrate 21 (first substrate) is prepared. A gate electrode pattern 32 and a gate line pattern (not illustrated) may be formed on the transfer substrate 21, for example, by a printing method such as a gravure method (FIG. 5A). The gate electrode pattern 32 and the gate line pattern are to be the gate electrode 12 and the gate line 12A later, respectively, by being cured later. As shown in FIG. 6, a protrusion portion 32P protruding upward (to the opposite side from the transfer substrate 21) is formed in circumferential edges of the gate electrode pattern 32 and the gate line pattern that have been formed by the printing method. The protrusion portion 32P is to be the protrusion portion 12P of the gate electrode 12 and the gate line 12A. On the other hand, bottom surfaces (surfaces in contact with the transfer substrate 21) of the gate electrode pattern 32 and the gate line pattern are planarized in accordance with the surface of the transfer substrate 21. The gravure method is a method to fill a concave plate having a predetermined pattern (a pattern corresponding to shapes of the gate electrode pattern 32 and the gate line pattern) with ink including an electrically-conductive material, and then, to transfer the ink onto the transfer substrate 21. As the transfer substrate 21, a material having a flat surface and having water repellency such as a blanket may be used, for example. The surface of the transfer substrate 21 may be made, for example, of a material having high surface free energy such as silicone resin and fluorine-containing rubber. The electrically-conductive material may be, for example, metal nanoparticles such as those described above. The ink is made by dispersing such metal nanoparticles into liquid such as water and organic solvent. Examples of the organic solvent may include hydrocarbon, alcohol, and ether. A dispersant for dispersing the metal nanoparticles may be added to the ink. The metal nanoparticles may be covered with a covering agent in order to prevent spontaneous aggregation of the metal nanoparticles. Other than the ink including the metal nanoparticles, printing may be performed with the use of, for example, liquid organic metal, electrically-conductive resin, or the like. The gate electrode pattern 32 and the gate line pattern formed on the transfer substrate 21 by the printing method are dried sufficiently to be cured tentatively.

The gate electrode pattern 32 and the gate line pattern may be formed by a printing method other than the gravure method such as an inkjet method, a screen printing method, a flexo-printing method, and a reverse printing method. Alternatively, an electrically-conductive film may be formed on the transfer substrate 21, for example, by deposition, sputtering, etc., and then, the formed electrically-conductive film may be patterned by photolithography to form the gate electrode 12 and the gate line 12A.

After the gate electrode pattern 32 and the gate line pattern are dried on the transfer substrate 21, a pre-cured embedding film 32I is formed on the entire surface of the transfer substrate 21 so as to cover the dried gate electrode pattern 32 and gate line pattern (FIG. 5B). Specifically, the surface of the transfer substrate 21 is coated with ink obtained by dissolving an insulating material configuring the embedding film 12I into liquid such as water and organic solvent, and the surface of the transfer substrate 21 is planarized. Thereafter, the resultant is dried for a predetermined time. Examples of the organic solvent configuring the ink may include ester, alcohol, and ether. For example, a surfactant etc. may be added to the ink in order to improve coating characteristics. The ink including the insulating material may be applied onto the transfer substrate 21, for example, by a spin coating method, a dip coating method, a slit coating method, a spray coating method, a roll coating method, or the like. The ink may preferably have fluidity also after the application, and the pre-cured embedding film 32I (embedding film 12I) may be preferably planarized. Therefore, a boiling point and viscosity of the liquid (water or an organic solvent) included in the ink may be adjusted according to, for example, the coating method to be used and/or the like.

Subsequently, as shown in FIG. 5C, the pre-cured embedding film 32I on the transfer substrate 21 is allowed to face the substrate 11, and the gate electrode pattern 32, the gate line pattern, and the pre-cured embedding film 321 are transferred from the transfer substrate 21 to the substrate 11. In other words, the transfer substrate 21 is peeled off from the gate electrode pattern 32, the gate line pattern, and the pre-cured embedding film 32I, and thereby, the surfaces of the gate electrode pattern 32, the gate line pattern, and the pre-cured embedding film 32I that have been in contact with the transfer substrate 21 are exposed. Thereafter, the gate electrode pattern 32, the gate line pattern, and the pre-cured embedding film 32I may be, for example, heated at a temperature from 120° C. to 200° C. both inclusive for a predetermined time on the substrate 11 and thereby cured. The covering agent in the ink is volatized by heating, and the metal particles become in contact with each other. In other words, electrical conductivity is exhibited, and thereby, the gate electrode 12, the gate line 12A, and the embedding film 12I are formed (FIG. 5D). In the present embodiment, such a transfer process is used. Therefore, an embedded structure having high flatness is achieved through utilizing the surface of the transfer substrate 21. This will be described in detail below.

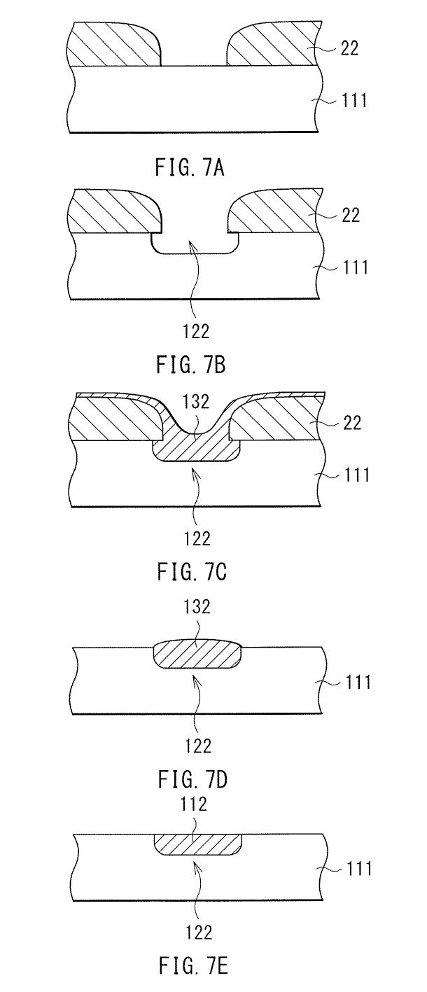

FIGS. 7A to 7E illustrate a method of manufacturing a gate electrode 112 having an embedded structure according to a comparative example (for example, see JP 2008-251814A). In this method, first, a concave section 122 is formed on a substrate 111 with the use of a mask 22 (FIGS. 7A and 7B). Thereafter, electrically-conductive paste 132 is applied inside the concave section 122 (FIG. 7C). Subsequently, the mask 22 and the electrically-conductive paste 132 attached to the mask 22 is peeled off (FIG. 7D). Thereafter, the electrically-conductive paste 132 inside the concave section 122 is fired, and thereby, the gate electrode 112 is formed (FIG. 7E). In the method in which such a concave section 122 is provided to form the embedded structure, for example, when the mask 22 is peeled off, a burr may be caused in the electrically-conductive paste 132. Moreover, because the electrically-conductive paste 132 inside the concave section 122 is removed together with the mask 22, the gate electrode 112 is not allowed to be molded into a favorable shape. Moreover, when the electrically-conductive paste 132 is fired, volume of the electrically-conductive paste 132 is contracted. Therefore, the thickness of the gate electrode 112 becomes non-uniform, which may cause a void in the gate electrode 112.

It may be possible to consider about forming the concave section without using a mask (for example, see JP H6-163586A, JP H4-324938A, JP H7-333648A, and JP 2003-78171A). However, it may be difficult to prevent burrs from being caused in any of the methods. For example, a process such as polishing may be performed in order to remove the burrs. However, this increases the number of processes, and also, may degrade the characteristics of the functional film. Moreover, if the electrically-conductive paste 132 is cured inside the concave section 122 in the substrate 111, the contraction of the electrically-conductive paste 132 causes the smoothness between the electrically-conductive paste 132 and the substrate 111 to be difficult to be maintained. In addition thereto, adhesiveness between the substrate 111 and the gate electrode 112 may be degraded.

On the other hand, in the TFT 1, the embedded structure of the gate electrode 12 and the gate line 12A is formed by the transfer process. Therefore, the gate electrode pattern 32, the gate line pattern, and the pre-cured embedding film 32I are formed in accordance with the surface of the transfer substrate 21. In other words, the gate electrode 12 and the gate line 12A are formed to have the surfaces on the same plane on which the surface of the embedding film 12I is formed, and therefore, the embedded structure having high flatness is achieved. Moreover, by tentatively curing the gate electrode pattern 32 and the gate line pattern in advance, the gate electrode 12 and the gate line 12A are controlled to have favorable shapes and thicknesses. Accordingly, materials are allowed to be selected irrespective of the magnitude of the volume contraction rate. Moreover, by curing the gate electrode pattern 32, the gate line pattern, and the pre-cured embedding film 32I at the same time, adhesiveness between the gate electrode 12 and the embedding film 12I and between the gate line 12A and the embedding film 12I is improved. The high adhesiveness is similarly achieved also by curing the pre-cured embedding film 32I after curing the gate electrode pattern 32 and the gate line pattern. In addition thereto, by forming the gate electrode pattern 32 and the gate line pattern by a printing method, the gate electrode 12 (the gate electrode pattern 32) and the gate line 12A (the gate line pattern) that have the same thickness is obtained easily in short processes.

After forming the gate electrode 12 and the gate line 12A having the embedded structure in such a way, the gate insulating film 13 is formed on the embedding film 12I. The gate insulating film 13 may be formed, for example, by applying PGMEA (Propylene Glycol Monomethyl Ether Acetate) solution of polyvinyl phenol onto the embedding film 12I, the gate electrode 12, and the gate line 12A by a spin coating method, and then performing a thermal process at 150° C. thereon. Subsequently, for example, the source electrode 14A, the drain electrode 14B, and the source line 14C that are made of gold may be formed on the gate insulating film 13. The source electrode 14A, the drain electrode 14B, and the source line 14C may be formed, for example, by forming a film of gold on the entire surface of the gate insulating film 13 by a vacuum evaporation method, and then patterning the resultant by photolithography. The source electrode 14A, the drain electrode 14B, and the source line 14C may be formed by a coating method, a printing method, or a plating method.

Subsequently, the semiconductor film 15 may be formed on the top surfaces of the source electrode 14A and the drain electrode 14B, and in the gap between the source electrode 14A and the drain electrode 14B. The semiconductor film 15 may be formed, for example, by a inkjet printing method with the use of xylene solution of TIPS pentacene (6,13-bis(triisopropylsilylethynyl)pentacene). By the above-described processes, the TFT 1 is completed. After forming the TFT 1, the passivation film 16 is formed on the entire surface of the substrate 11, and thereby, the pixel electrode 17 on the passivation film 16 is electrically connected to the TFT 1 via the contact hole 16H in the passivation film 16. Accordingly, the TFT 1 may serve, for example, as a driving device of a display etc.

In the TFT 1, when a gate voltage which has a value equal to or higher than a predetermined threshold is applied to the gate electrode 12, a channel is formed in the semiconductor film 15, and a current (a drain current) flows between the source electrode 14A and the drain electrode 14B. Thus, the TFT 1 serves as a transistor. In this example, because the transfer process is used when the gate electrode 12 and the gate line 12A having the embedded structure are formed, the surface of the transfer substrate 21 is allowed to be utilized. Therefore, high flatness is achieved between the surface of the embedding film 12I and the surfaces of the gate electrode 12 and the gate line 12A. Accordingly, occurrence of disconnection in the wirings in the upper layers etc. is suppressed.

Moreover, the shapes and the thicknesses of the gate electrode 12 and the gate line 12A are allowed to be controlled in advance with the use of the gate electrode pattern 32 and the gate line pattern. Therefore, the materials of the gate electrode 12 and the gate line 12A are allowed to be selected irrespective of the magnitude of the rate of the volume contraction caused by heating.

As described above, the TFT 1 according to the present embodiment, the embedded structures of the gate electrode 12 and the gate line 12A are formed by the transfer process. Therefore, high flatness is achieved.

A modification of the embodiment of the present technology will be described below. Components common to those in the above-described embodiment will be denoted with the same numerals and will not be described further.

### MODIFICATION

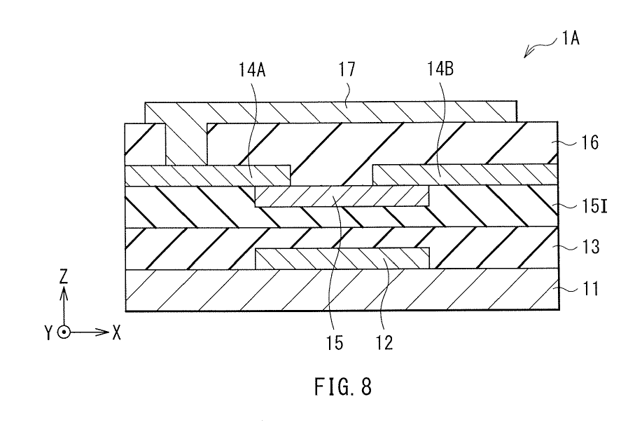

FIG. 8 illustrates a cross-sectional configuration of a TFT (TFT 1A) according to a modification of the above-described embodiment. The TFT 1A includes the gate electrode 12, the gate insulating film 13, and the semiconductor film 15 having an embedded structure, and a pair of the source electrode 14A and the drain electrode 14B in order on the substrate 11. In other words, the TFT 1A has a top-contact bottom-gate structure. Except for this point, the TFT 1A has a configuration similar to that of the TFT 1, and has functions and effects similar to those of the TFT 1.

In the TFT 1A, the semiconductor film 15 is embedded in an insulating embedding film 151, and a surface of the semiconductor film 15 and the front surface of the embedding film 151 configure the same plane. The semiconductor 15 exposed from the front surface of the embedding film 151 is in contact with the source electrode 14A and the drain electrode 14B, and thereby the semiconductor film 15 is electrically connected to the source electrode 14A and the drain electrode 14B. Therefore, a level difference caused by a semiconductor film is not caused for the source electrode 14A and the drain electrode 14B. Therefore, occurrence of disconnection etc. in the source electrode 14A and the drain electrode 14B is prevented. The embedded structure of the semiconductor film 15 is formed by the transfer process utilizing the surface of the transfer substrate 21 as in the above-described embodiment. Therefore, high flatness is achieved. In the TFT 1A, the gate insulating film 13 may be omitted and the embedding film 151 may be configured to also serve as a gate insulating film.

### APPLICATION EXAMPLE

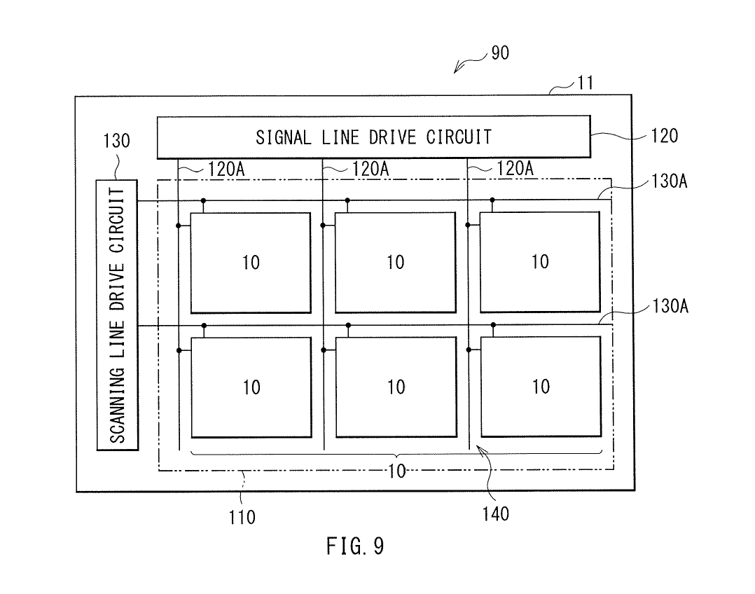

FIG. 9 illustrates a general configuration of a display (a display 90) that includes the above-described TFT 1 or the above-described TFT 1A as a driving device. The display 90 may be, for example, a display such as a liquid crystal display, an organic EL display, and an electronic paper display. The display 90 may include, for example, a plurality of display elements 10 and various drive circuits for driving the display elements 10. The display elements 10 are arranged in a matrix in a display region 110 on the substrate 11. On the substrate 11, as drive circuits, a signal line drive circuit 120 and a scanning line drive circuit 130 that are drivers for image display, and a pixel drive circuit 140 may be provided, for example. A sealing panel which is not illustrated is attached onto the substrate 11, and the sealing panel seals the above-described drive circuits, a display layer (not illustrated), etc. between the sealing panel and the substrate 11.

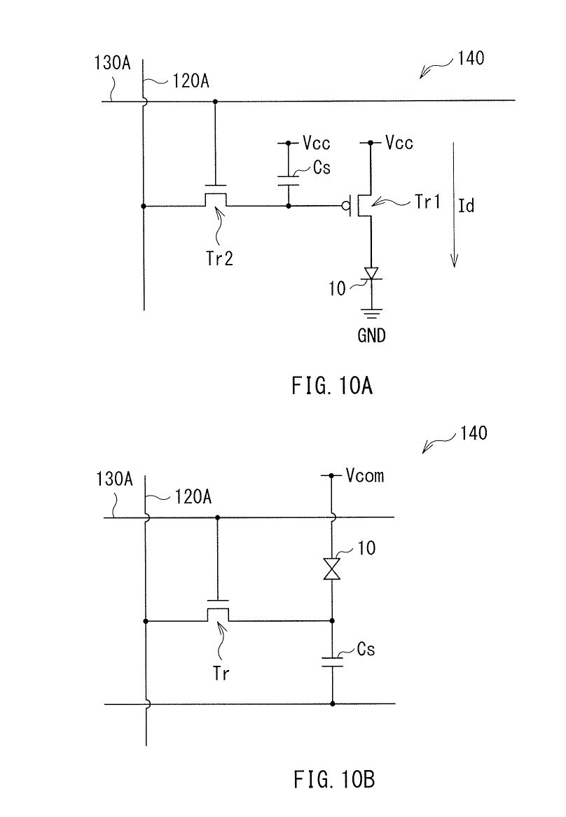

FIG. 10A is a circuit diagram of the pixel drive circuit 140. The pixel drive circuit 140 is an active drive circuit in which transistors Tr1 or transistors Tr2, or both are provided as the above-described TFTs 1 or 1A. A capacitor Cs is provided between each transistor Tr1 and each transistor Tr2. The display element 10 is connected to the transistor Tr1 in series between a first power line (Vcc) and a second power line (GND). In such a pixel drive circuit 140, a plurality of signal lines 120A are arranged in a column direction, and a plurality of scanning lines 130A are arranged in a row direction. The respective signal lines 120A are connected to the signal line drive circuit 120. The signal line drive circuit 120 supplies image signals to source electrodes of the transistors Tr2 via the signal lines 120A. The respective scanning lines 130A are connected to the scanning line drive circuit 130. The scanning line drive circuit 130 sequentially supplies scanning signals to gate electrodes of the transistors Tr2 via the scanning lines 130A. As shown in FIG. 10B, only the transistors Tr1 may be used as the transistors of the pixel driving circuit 140. In the display 90, the transistors Tr1 and Tr2 are each configured of the above-described TFT 1 or 1A. Therefore, yield of the display 90 is improved. Such a display 90 may be mounted, for example, on an electronic apparatus shown in Application Examples 1 to 7 described below.

### Application Example 1

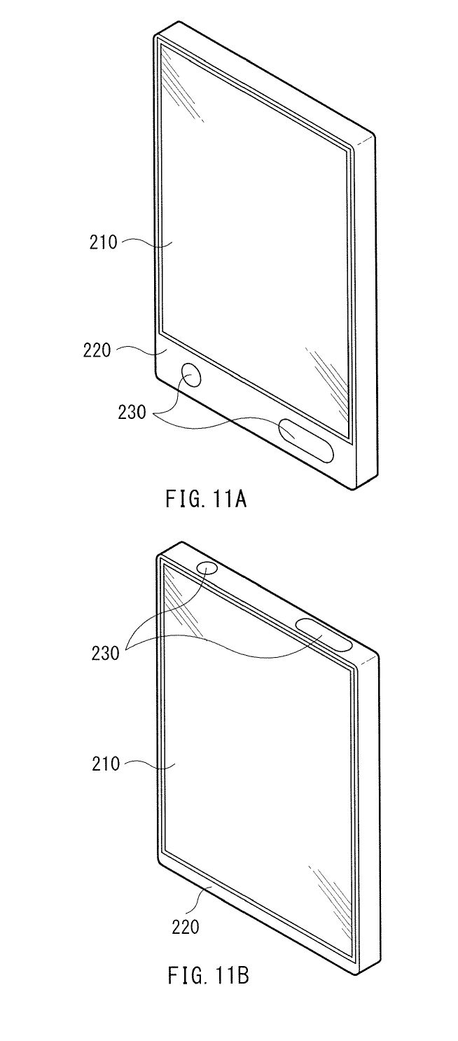

FIGS. 11A and 11B each illustrate an appearance of an electronic book reader. The electronic book reader may include, for example, a display section 210 and a non-display section 220. The non-display section 220 includes an operation section 230. The display section 210 is configured of the above-described display 90. The operation section 230 may be formed on the same surface (front surface) on which the display section 210 is formed as shown in FIG. 11A, or may be formed on a surface (top surface) different from a surface on which the display section 210 is formed as shown in FIG. 11B.

### Application Example 2

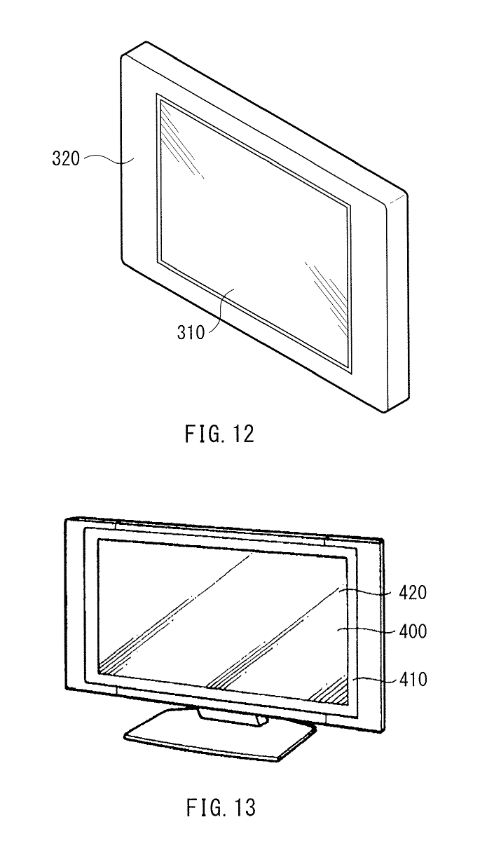

FIG. 12 illustrates an appearance of a tablet personal computer. The tablet personal computer may include, for example, a touch panel section 310 and a housing 320. The touch panel section 310 is configured of the above-described display 90.

### Application Example 3

FIG. 13 illustrates an appearance of a television. The television may include, for example, an image display screen section 400 that includes a front panel 410 and a filter glass 420. The image display screen section 400 is configured of the above-described display 90.

### Application Example 4

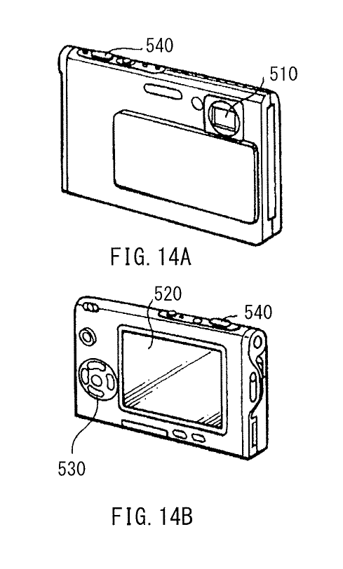

FIGS. 14A and 14B each illustrate an appearance of a digital still camera. The digital still camera may include, for example, a light emitting section 510 for flash, a display section 520, a menu switch 530, and a shutter button 540. The display section 520 is configured of the above-described display 90.

### Application Example 5

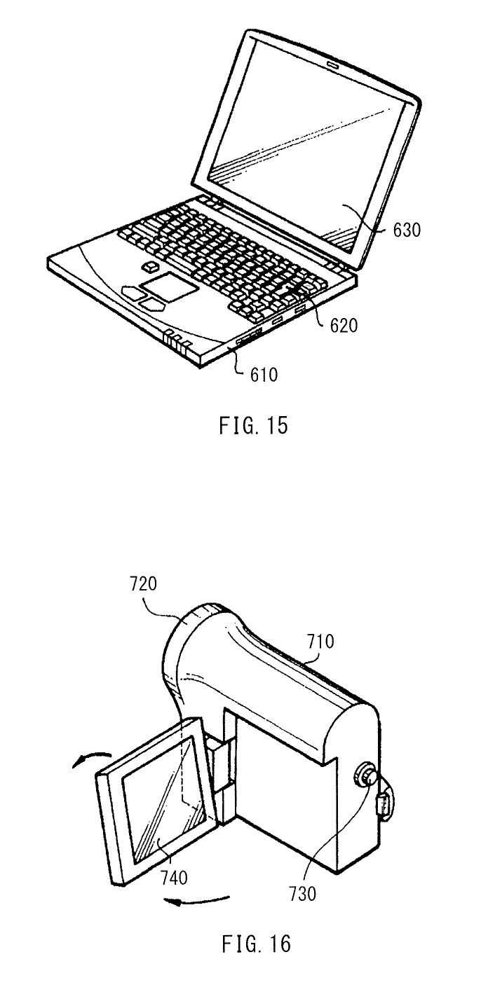

FIG. 15 illustrates an appearance of a notebook personal computer. The notebook personal computer may include, for example, a main body 610, a keyboard 620 for input operation of characters etc., and a display section 630 displaying an image. The display section 630 is configured of the above-described display 90.

### Application Example 6

FIG. 16 illustrates an appearance of a video camcorder. The video camcorder may include, for example, a main body section 710, a lens 720 for shooting a subject provided on a front side surface of the main body section 710, a start-stop switch 730 used for shooting, and a display section 740. The display section 740 is configured of the above-described display 90.

### Application Example 7

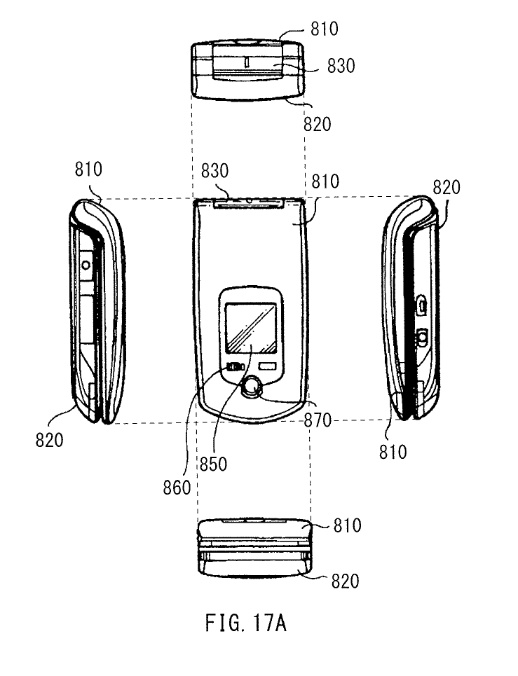

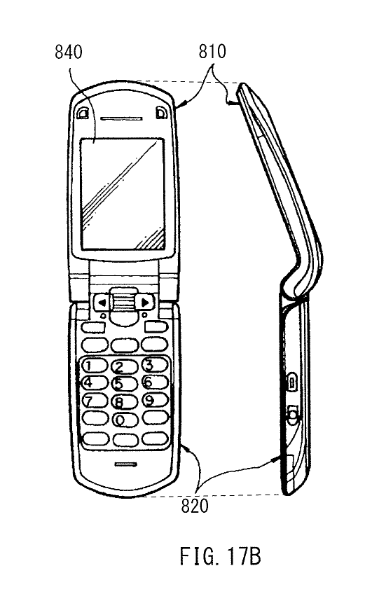

FIGS. 17A and 17B each illustrate an appearance of a mobile phone. The mobile phone may include, for example, an upper housing 810 and a lower housing 820 connected by a connection section (hinge section) 830, a display 840, a sub-display 850, a picture light 860, and a camera 870. One or both of the display 840 and the sub-display 850 are each made of the above-described display 90.

The present technology has been described above referring to the embodiment and the modification thereof. However, the present technology is not limited to the above-described embodiment and the like, and may be variously modified. For example, the TFT of the bottom-gate type has been described in the above embodiment and the like. However, the embodiment of the present technology may be also applicable to a TFT of a top-gate type.

Moreover, the case in which the embedding film 12I is provided on the substrate 11 has been described above in the embodiment and the like. However, the substrate 11 may be removed after the transfer process, and the embedding film 12I itself may be allowed to serve as a substrate.

Moreover, the embedded structures of the gate electrode 12 and the gate line 12A (electrically-conductive film) and the embedded structure of the semiconductor film 15 have been shown in the above-described embodiment and the like. However, the present embodiment may be also applicable to an embedded structure of the functional film other than the foregoing embedded structures.

Moreover, the description has been given referring to the TFT as an example of a thin film device in the above embodiment and the like. However, the embodiment of the present technology is also applicable to thin film devices other than the TFT.

Moreover, for example, the materials, the thicknesses, the forming methods, the forming conditions, etc. of the respective layers described in the above embodiment and the like are not limitative, and other materials, thicknesses, forming methods, and forming conditions may be used.

It is possible to achieve at least the following configurations from the above-described example embodiments and the modifications of the disclosure.

(1) A method of manufacturing a thin film device, the method including:
forming a functional film having a predetermined pattern on a surface of a first substrate;
covering the surface of the first substrate and the functional film with an insulating film; and
transferring the insulating film and the functional film from the first substrate to a second substrate.
   (2) The method according to (1), wherein the surface of the first substrate is flat, and a surface of the functional film after the transferring and a surface of the insulating film configure a same plane.
   (3) The method according to (1) or (2), wherein the functional film is formed by a printing method.
   (4) The method according to any one of (1) to (3), wherein the surface of the first substrate has water repellency.
   (5) The method according to any one of (1) to (4), wherein the surface of the first substrate is covered with the insulating film after the functional film is dried for a predetermined time.
   (6) The method according to any one of (1) to (5), wherein the functional film is configured of an electrically-conductive film.
   (7) The method according to (6), wherein the functional film is configured of a gate electrode and a gate line.
   (8) The method according to any one of (1) to (5), wherein the functional film is configured of a semiconductor film.
   (9) A method of manufacturing a display, the method including
forming a thin film device, the forming including
forming a functional film having a predetermined pattern on a surface of a first substrate,
covering the surface of the first substrate and the functional film with an insulating film, and
transferring the insulating film and the functional film from the first substrate to a second substrate.
   (10) A thin film device including:
an insulating film; and
a functional film embedded in the insulating film and having a surface that configures a same plane configured of a surface of the insulating film, the functional film including a protrusion portion protruding toward a back surface of the insulating film.

It should be understood by those skilled in the art that various modifications, combinations, sub-combinations, and alterations may occur depending on design requirements and other factors insofar as they are within the scope of the appended claims or the equivalents thereof.

What is claimed is:

1. A method of manufacturing a thin film device, the method comprising:
forming a functional film having a predetermined pattern on a surface of a first substrate;
covering the surface of the first substrate and the functional film with an insulating film; and
transferring the insulating film and the functional film from the first substrate to a second substrate.

2. The method according to claim 1, wherein the surface of the first substrate is flat, and a surface of the functional film after the transferring and a surface of the insulating film configure a same plane.

3. The method according to claim 1, wherein the functional film is formed by a printing method.

4. The method according to claim 1, wherein the surface of the first substrate has water repellency.

5. The method according to claim 1, wherein the surface of the first substrate is covered with the insulating film after the functional film is dried for a predetermined time.

6. The method according to claim 1, wherein the functional film is configured of an electrically-conductive film.

7. The method according to claim 6, wherein the functional film is configured of a gate electrode and a gate line.

8. The method according to claim 1, wherein the functional film is configured of a semiconductor film.

9. A method of manufacturing a display, the method comprising
forming a thin film device, the forming including
forming a functional film having a predetermined pattern on a surface of a first substrate,
covering the surface of the first substrate and the functional film with an insulating film, and
transferring the insulating film and the functional film from the first substrate to a second substrate.

10. A thin film device comprising:
an insulating film; and
a functional film embedded in the insulating film and having a surface that configures a same plane configured of a surface of the insulating film, the functional film including a protrusion portion protruding toward a back surface of the insulating film.
